(19) United States
(12) Patent Application Publication
(10) Pub. No.: US 2011/0151588 A1
(43) Pub. Date: Jun. 23, 2011

(54) METHOD AND MAGNETIC TRANSFER STAMP FOR TRANSFERRING SEMICONDUCTOR DICE USING MAGNETIC TRANSFER PRINTING TECHNIQUES

(75) Inventors: Ian Ashdown, West Vancouver (CA); Ingo Speier, Saanichton (CA); Calvin Wade Sheen, Derry, NH (US); Philippe Michael Schick, Vancouver (CA)

(73) Assignee: COOLEDGE LIGHTING, INC., Vancouver (CA)

(21) Appl. No.: 12/966,997

(22) Filed: Dec. 13, 2010

Related U.S. Application Data
(60) Provisional application No. 61/287,445, filed on Dec. 17, 2009.
(60) Provisional application No. 61/287,797, filed on Dec. 18, 2009.
(60) Provisional application No. 61/375,127, filed on Aug. 19, 2010.

(51) Int. Cl. H01L 21/50

(52) U.S. Cl. 438/3; 438/107; 257/E21.499

(57) ABSTRACT

Releasable semiconductor dice are deposited with a magnetic layer and held by magnetic forces to a magnetic or electromagnetic transfer stamp for the transfer of the dice from a host substrate directly or indirectly to a target substrate.

This patent application claims the benefit of U.S. provisional application Nos. 61/287,445, 61/287,797 and 61/375,127, respectively filed Dec. 17, 2009, Dec. 18, 2009 and Aug. 19, 2010. The disclosures of said provisional applications are hereby incorporated herein by reference thereto.

### TECHNICAL FIELD

The subject matter of the present invention is directed generally to the manufacture of circuits with transferable semiconductor dice and, more particularly, is concerned with a method and magnetic transfer stamp for transferring semiconductor dice from a host substrate to a target substrate using magnetic (or electromagnetic) transfer printing techniques.

### BACKGROUND ART

Illumination based on semiconductor light sources, such as light-emitting diodes (LEDs), offers an efficient and long-lived alternative to fluorescent, high-intensity discharge and incandescent lamps. Many LED light sources employ high powered LEDs, which pose thermal management problems and other related problems. Another drawback with state of the art LED devices is their high initial cost.

Small semiconductor dice including those with sizes of 300 um or smaller provide numerous benefits in applications such as broad area lighting, concentrator photovoltaics and electronics. Devices of this scale cannot be transferred from a source wafer or host substrate to a target substrate utilizing conventional pick and place technology. One technique is transfer printing, for example using composite patterning devices comprising a plurality of polymer layers each having selected values of mechanical properties, such as Young's Modulus and flexural rigidity; selected physical dimensions, such as thickness, surface area and relief pattern dimensions; and selected thermal properties, such as coefficients of thermal expansion and thermal conductivity; to provide high resolution patterning on a variety of substrate surfaces and surface morphologies.

There is therefore a need for an innovation whereby small semiconductor dice can be efficiently and effectively transferred from a host substrate to a target substrate.

### SUMMARY OF THE INVENTION

The subject matter of the present invention is directed to such an innovation which relates to a method and magnetic transfer stamp for transferring semiconductor dice from a host substrate to a target substrate using magnetic or electromagnetic transfer printing techniques. For the sake of brevity the terms such as “magnetic” and “magnet” are also meant respectively to include “electromagnetic” and “electromagnet”.

In one aspect of the invention, a method is provided for transferring semiconductor dice from a host substrate to a target substrate wherein the method includes the steps of providing a host substrate with semiconductor dice having magnetized portions, magnetizing regions of a selected one of a transfer stamp or a target substrate, and transferring the semiconductor dice from the host substrate to the magnetized regions of the selected one of the transfer stamp or target substrate by magnetic force between the magnetized regions and portions when the host substrate is positioned adjacent to the selected one of the transfer stamp or target substrate. The transferring step, when the selected one is the transfer stamp, also includes releasing the semiconductor dice from the transfer stamp to the target substrate.

In another aspect of the invention, a method is provided for transferring semiconductor dice from a host substrate to a target substrate wherein the method includes the steps of providing a host substrate with semiconductor dice having magnetized portions, magnetizing regions of a transfer stamp, removing the semiconductor dice from the host substrate using the magnetize regions of the transfer stamp, and releasing the semiconductor dice from the transfer stamp onto a target substrate by at least removing the transfer stamp or providing an adhesive force between the semiconductor dice and the target substrate that is greater than the magnetic force between the semiconductor dice and the transfer stamp.

In a further aspect of the invention, a transfer stamp for transferring semiconductor dice from a host substrate to a target substrate wherein the stamp includes a substrate and an array of magnetized regions thereon. The substrate includes spaced mesas formed thereon having the magnetized regions.

### BRIEF DESCRIPTION OF THE DRAWINGS

For clarity, the drawings herein are not necessarily to scale, and have been provided as such in order to illustrate the principles of the subject matter, not to limit the invention.

FIG. 1 is a schematic view of a host substrate with semiconductor dice and tethers.

FIG. 2 is a schematic view of a host substrate with semiconductor dice, tethers and a sacrificial layer.

FIG. 3 is a schematic view of a host substrate with semiconductor dice, tethers, a sacrificial layer and a magnetic photoresist layer.

FIG. 4 is a schematic view of a host substrate with semiconductor dice, tethers and magnets.

FIG. 5 is a schematic view of a magnetic transfer stamp being brought into contact with magnets on semiconductor dice.

FIG. 6 is a schematic view of a magnetic transfer stamp that has picked up semiconductor dice.

FIG. 7 is a schematic view of a magnetic transfer stamp about to transfer semiconductor dice to a target substrate.

FIG. 8 is a schematic view of a target substrate mounted with semiconductor dice and magnets.

FIG. 9 is a schematic view of a target substrate with the magnets having been removed from the semiconductor dice.

FIG. 10 is a flow diagram of a method for transferring semiconductor dice.

FIG. 11 is a flow diagram of an alternate embodiment of the method involving a stamp with writeable and erasable magnetic transfer heads.

FIG. 12 is a schematic view of a transfer stamp with electromagnets.

FIG. 13 is a flow diagram of a method for transferring semiconductor dice from a host substrate to a target substrate using an electromagnetic transfer stamp.

FIG. 14 is a schematic view of a host substrate being brought into contact with a target substrate.

FIG. 15 is a schematic view of a host substrate removed from a target substrate, having transferred semiconductor dice thereto.

FIG. 16 is a schematic view of LEDs on a host substrate with an approaching magnetic transfer stamp.

FIG. 17 is a schematic view of laser-lifting of LEDs from a host substrate while contacted to a magnetic transfer stamp.

FIG. 18 is a schematic view of LEDs with a residual decomposition layer after having been removed from a host substrate by a magnetic transfer stamp.

FIG. 19 is a schematic view of LEDs being brought onto a rigid temporary carrier.

FIG. 20 is a schematic view of LEDs on a rigid temporary carrier.

FIG. 21 is a schematic view of a selective electromagnetic pickup device that has picked up an LED.

FIG. 22 is a schematic view of an LED transferred to a target substrate with a phosphor zone.

FIG. 23 is a schematic view of an array of LEDs on a target substrate with microlenses.

FIG. 24 is a flow diagram of an alternative method involving a temporary carrier.

### DESCRIPTION OF EMBODIMENTS

The term semiconductor die (plural: dice) includes light-emitting elements, which are any devices that emit electromagnetic radiation within a wavelength regime of interest, for example, visible, infrared or ultraviolet regime, when activated, by applying a potential difference across the device or passing a current through the device. Examples of light-emitting elements include solid-state, organic, polymer, phosphor-coated or high-flux light-emitting diodes (LEDs), micro-LEDs, laser diodes or other similar devices as would be readily understood. Without limiting the foregoing, micro-LEDs include LEDs with semiconductor die with lateral dimensions of 300 microns or smaller. The output radiation of an LED may be visible, such as red, blue or green, or invisible, such as infrared or ultraviolet. An LED may produce radiation of a spread of wavelengths or multiple discrete wavelengths. An LED may comprise a phosphorescent material such as cerium-activated yttrium-aluminum-garnet (YAG:Ce³⁺) for converting all or part of its output from one wavelength to another. An LED may comprise multiple LEDs, each emitting essentially the same or different wavelengths.

While LEDs may be examples of transferable elements that may be transferred by the method of the present invention, other semiconductor dice may also be transferred, for example, integrated circuits, photovoltaic cells (for example single-junction or multijunction cells for concentrator photovoltaic applications), transistors, photodiodes, laser diodes, resistors, capacitors, and non-emitting diodes. Semiconductor dice transferred by the disclosed method may be used in electronic devices or in modules that may be incorporated in electronic devices. For example, a luminaire may comprise elements transferred by the method of the disclosed invention.

### Exemplary Embodiments

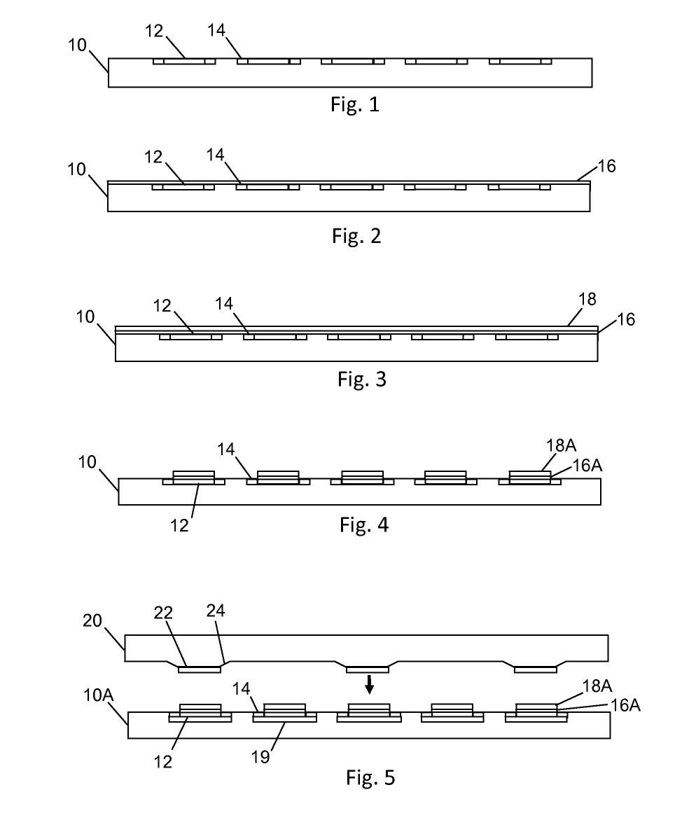

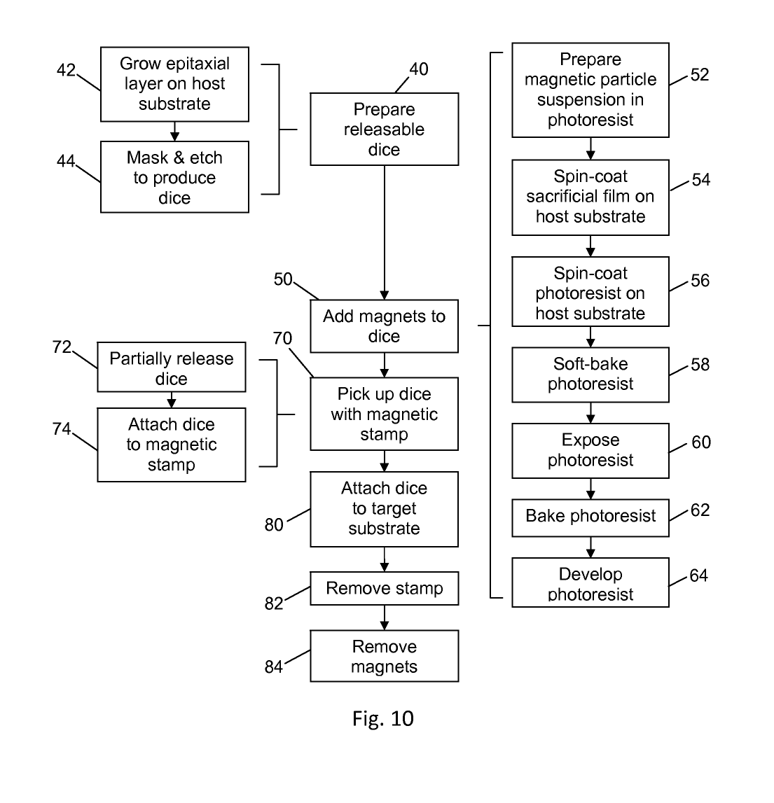

Referring now to FIGS. 1-10, there is shown in FIGS. 4-8 a magnetic transfer stamp 20 and in FIGS. 1-9 a succession of stages in accordance with the basic steps of a method depicted in a flow diagram in FIG. 10 that uses the magnetic transfer stamp 20 and magnetic transfer printing techniques to transfer semiconductor dice 12 from a suitable host substrate 10 to a target substrate 30, in accordance with the present invention. In regard the flow diagram of FIG. 10, the main steps of the method are shown in the central column, with more detailed steps shown to either side.

Initially, at step 40 of the flow diagram of FIG. 10, an array of releasable semiconductor dice 12 is prepared on the host substrate 10. This involves performance of steps 42 and 44. In step 42, epitaxially growing multiple epitaxial layers in the form of a series of one or more semiconductor films such as for example indium gallium nitride (InGaN) on a surface of the host substrate 10, such as for example sapphire or silicon, to form a semiconductor structure, as shown in FIG. 1. The semiconductor structure includes the semiconductor dice 12 that are connected to tethers 14 that are in turn connected to the host substrate 10. The semiconductor dice 12 are grown to be later releasable from the host substrate 10 by the removal or breakdown of material at or adjacent to the interface between the semiconductor dice 12 and the host substrate 10. In step 44, masking and etching of the epitaxial layers to form the array of releasable semiconductor dice 12. Preferably the array of releasable semiconductor dice 12 is as dense as possible in order to maximize usage of the materials.

In step 50 of the flow diagram of FIG. 10, permanent magnets are added to the semiconductor dice 12. This step 50 involves performance of steps 52-64. In step 52 of the flow diagram of FIG. 10, a suspension of magnetic particles in a photoresist is prepared. In step 54, a thin sacrificial organic film 16, such as OmniCoat from MicroChem, MA, is spin-coated onto the host substrate 10 as seen in FIG. 2, using known spin-coating techniques, to a thickness of no less than 17 nm, or otherwise, as recommended by the manufacturer.

Following next in step 56 of the flow diagram of FIG. 10, a photoresist 18 having the suspension of magnetic particles, as prepared in step 52, is spin-coated onto the sacrificial film 16 on the host substrate 10 as seen in FIG. 3, using known spin-coating techniques.

More particularly, the magnetic particle photoresist 18 may be prepared by, for example, mixing a nickel powder such as 43338 (spherical, APS 80-150 nm) from Alfa Aesar, IL in a photoresist material such as SU8-50 from MicroChem, MA with a weight ratio of approximately 1:8 until a homogeneous suspension is obtained. Note that a non-oxidative atmosphere such as argon or nitrogen may be required to prevent the nickel powder from undergoing spontaneous combustion unless the nickel particles are passivated by a non-reactive coating. Other weight ratios may also be employed, depending on the physical and chemical properties of the nickel powder and photoresist.

Other ferromagnetic or ferrimagnetic metals and metal alloys may alternatively be employed in the magnetic particle photoresist 18, including for example iron (Fe), cobalt (Co), gadolinium (Gd), dysprosium (Dy), ferrites such BaFe₁₂O₁₉ and SrFe₁₂O₁₉, metal alloys such as Al—Ni—Co, Fe—Pt, and Co—Pt, and rare-earth alloys such as SmCo₅, Sm₂Co₁₇, and Nd₂Fe₁₄B. As a further alternative, a superparamagnetic material may be employed for the magnetic particles. For example, magnetite (Fe₃O₄) particles such as fluidMAG-UC from Chemicell GmbH (Berlin, Germany) may be used. The advantage of superparamagnetic particles is that they have no remanent magnetization and so do not agglomerate as do ferromagnetic materials. This makes them resistant to agglomeration in low-viscosity photoresists and so more suitable for spin coating of thin films.

After the magnetic particles have been mixed with the photoresist, the resulting suspension is then left undisturbed for approximately 12 hours to allow gas bubbles to separate, following which the photoresist should be used within 48 hours to avoid settling of the magnetic particles. Alternately, the degassing process may be accelerated by storing the suspension in a partial vacuum generated with, for example, an aspirator. In still further alternate embodiments, heating the solution to 50 to 60 degrees Celsius for about 30 minutes may also degas the suspension by decreasing the photoresist viscosity, albeit at increased risk of particle agglomeration. Optionally, the addition of a viscosity-increasing agent or the choice of a more viscous photoresist (e.g. SU8-100) may prevent or reduce the agglomeration due to magnetic attraction of the magnetic particles, although this may inhibit spin-coating of thin films. If necessary, a surfactant such as gamma-butyrolactone (GBL) from Chemicell GmbH (Berlin, Germany) may be applied to the ferromagnetic or superparamagnetic particles to obtain steric stabilization and so further alleviate any tendency to agglomerate.

The desired spin-coat thickness may vary depending on the weight ratio of the ferromagnetic or superparamagnetic particles in the photoresist. As shown by Kobayashi et al. [2008], the photoactivated curing depth of the photoresist is dependent on the concentration of magnetic particles, and so more concentrated magnetic particle photoresists 18 may necessitate spin-coating in thinner layers in order to be effectively cured. As reported by Suter et al. (2009), magnetite strongly absorbs ultraviolet radiation and hinders crosslinking at depth in the photoresist. As an example, a film thickness of 3 μm permitted a maximum concentration in SU-8 photoresist of 3% Fe₃O₄ by weight.

In successive steps 58-64 of the flow diagram of FIG. 10, the magnetic particle photoresist 18 is soft-baked, exposed through a mask, baked again and then developed to result in a magnetic material 18A on top of each semiconductor die 12, as seen in FIG. 4. The magnetic material 18A may be, for example, a superparamagnetic material that does not retain a remanent field once the magnetizing field has been removed. Alternatively the magnetic material 18A may be a permanent magnet, for example a ferromagnetic material or ferrimagnetic that can be magnetized by exposure to a magnetic field. The photoresist film 18 is soft-baked in step 58 as per manufacturer's recommendations to evaporate the solvent and densify the photoresist film 18. After soft-baking, the photoresist film 18 is exposed through a mask to ultraviolet radiation with wavelengths between approximately 340 nm and 400 nm to cross-link the polymer. The mask allows only the photoresist portions deposited on the semiconductor elements 12 to be exposed. As many photoresists strongly absorb ultraviolet radiation below 350 nm, near-ultraviolet radiation in the range of 350 nm to 400 nm is therefore preferred to prevent “T-topping”, which is where only the top surface layer of the photoresist film is cross-linked. In step 62 the photoresist film is again baked to selectively cross-link the exposed portions of the photoresist film. Following this, in step 64 the photoresist is developed in a suitable developer such as SU-8 Developer from MicroChem, MA as per manufacturer's recommendations to remove the unexposed other portions of the photoresist 18 as seen in FIG. 4, thereby forming ferromagnetic or superparamagnetic permanent magnets 18A on the surface of each semiconductor element 12.

In step 70 of the flow diagram of FIG. 10, a magnetic transfer stamp 20 is used to pick up selected semiconductor dice 12 from the host substrate. This step 70 involves performance of steps 72 and 74. In step 72 of the flow diagram of FIG. 10, the portions of the sacrificial layer 16 extending between and not underlying the permanent magnets 18A are removed as seen in FIG. 4. This is followed by use of wet etchants to contact the portions of the substrate 10 underlying the permanent magnets 18A. As seen in FIG. 5, the semiconductor dice 12 have been partially released from the host substrate now denoted 10A using known wet etching techniques, with the semiconductor dice 12 remaining attached to the host substrate 10A by tethers 14. Wet-etching creates gaps 19 below each semiconductor die 12, such that the semiconductor dice 12 are effectively suspended over the host substrate 10A by the tethers 14. In other embodiments, laser lift-off techniques may be used instead of physical tethers.

In step 74 of the flow diagram of FIG. 10, the magnetic stamp 20 with magnets 22 mounted on mesas 24 in accordance with the present invention is also shown in FIG. 5. The magnetic stamp 20 is being brought into proximity or contact with the semiconductor dice 12 on the host substrate 10A such that the magnetic stamp 20 picks up the semiconductor dice 12. The magnetic stamp 20 may have an array of either permanent magnets or electromagnets (e.g., Guan et al. 2005 and Lee et al. 2008). The magnets 22 of the magnetic stamp 20 may align with one, some or all of the semiconductor dice 12 on the host substrate 10A, depending on which ones it is desired to select.

For example, the magnetic stamp 20 may have a rectangular array of magnets 22 that align with semiconductor dice 12 located at every m^{th} row and n^{th} column of a square array of dice on a host substrate 10A. A square array of semiconductor dice 12 on a host epiwafer substrate 10A may, for example, have a center-to-center spacing of 100 microns, and may be repetitively transferred to a target substrate with a center-to-center spacing of m×100 microns in one direction and a center-to-center spacing of n×100 microns in the orthogonal direction.

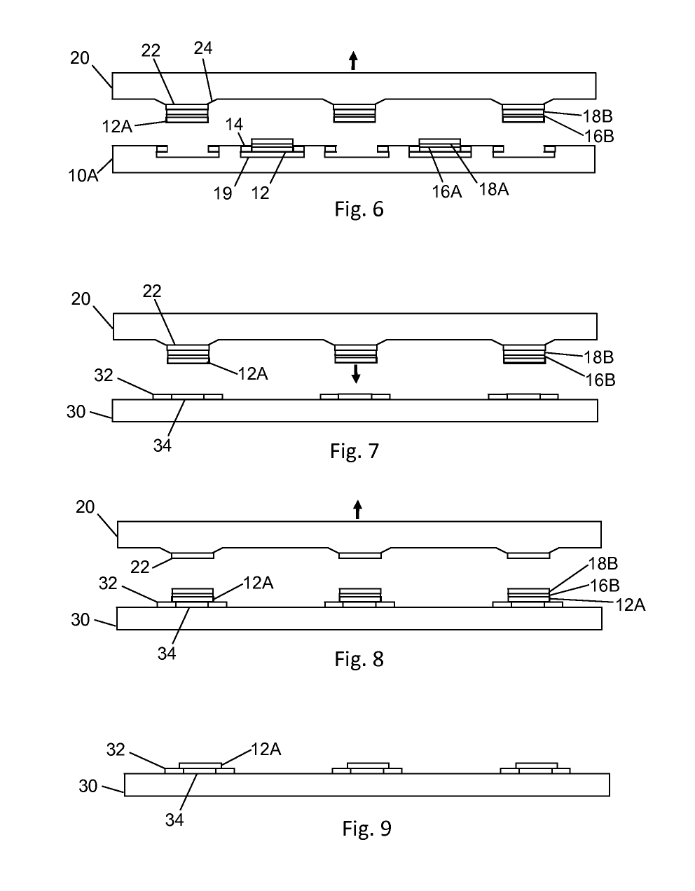

As a result of step 70 of the flow diagram of FIG. 10, selected semiconductor dice 12A are magnetically bound via their deposited permanent magnets 18B and intervening sacrificial layers 16B to the array of magnets 22 on the magnetic transfer stamp 20. As seen in FIG. 6, the selected semiconductor dice 12A are removed from the host substrate 10A as the magnetic stamp 20 is pulled away from the host substrate 10A and the corresponding tethers 14 are broken due to the magnetic force of attraction between the selected magnets 18B and the stamp magnets 22 causing fracturing of the corresponding tethers 14.

In successive steps 80 and 82 of the flow diagram of FIG. 10, the magnetic stamp 20 with the selected semiconductor dice 12A is then brought into contact with the target substrate 30 and then the magnetic stamp 20 with its magnets 22 are removed, as represented in FIGS. 7 and 8. The target substrate 30 carries metal interconnects 32 and adhesive areas 34 which line up and engage with the selected semiconductor dice 12A. The selected semiconductor dice 12A then become attached to the adhesive 34 and interconnects 32 of the target substrate 30, and the magnetic stamp 20 with its magnets 22 are removed.

In final step 84 of the flow diagram of FIG. 10, the magnets are removed from the semiconductor dice. In FIG. 8, the target substrate 30 is shown with selected semiconductor dice 12A mounted on adhesive areas 34 and electrically connected to interconnects 32. In FIG. 9, the portions of the sacrificial layer 16B, as seen in FIG. 8, that were on the selected semiconductor dice 12A, and the permanent magnets 18B that were used to transfer the semiconductor dice, have been removed by etching. The permanent magnets 18B may be removed from the semiconductor dice 12A by means of immersion in, for example, Remover PG from MicroChem, MA, following manufacturer's recommendations.

### Alternative Embodiments of Method and/or Transfer Stamp

In a first alternative embodiment, semiconductor dice 12 are removed from their host epiwafer substrate 10 by means of laser liftoff techniques rather than by fracturing tethers 14.

In a second alternative embodiment, semiconductor dice 12 are connected to their host epiwafer substrate 10 by tethers 14 that are more susceptible to fracturing, depending on the distribution of magnetic force applied thereto. The directions of the magnetic fields of the magnets 22 on the transfer stamp 20 may then be selected such that only semiconductor dice 12 with a specific orientation of tethers 14 may be successfully removed by fracturing.

In a third alternative embodiment, magnetic transfer substrate 20 is planar without mesas 24, and transfer of semiconductor dice 12A from a host epiwafer substrate 10 to the magnetic transfer stamp 20 is effected by means of magnetizing selected regions of the stamp 20.

In a fourth embodiment, the target substrate 30 includes mesas 24 upon which semiconductor dice 12A are deposited using the substantially planar magnetic transfer stamp 20 of the previous alternative embodiment.

In a fifth alternative embodiment, the tethers 14 connecting semiconductor dice 12 to their host epiwafer substrate 10A are broken by mechanical means (including the application of constant force upon the transfer stamp 20, ultrasonic vibration of the transfer stamp 20 or host epiwafer or substrate 10A, and shock waves or supersonic shock waves propagated through the transfer stamp 20 by means of ultrasonic transducers), the dice 12 being simultaneously held in place for transfer by magnetic forces.

In a sixth alternative embodiment and referring back to FIG. 5, the transfer stamp 20 has mesas 24, which are coated with a ferromagnetic coating 22. The ferromagnetic coating 22 may be selectively magnetized or demagnetized using a mechanically positioned magnetic write head similar to those used to record information on hard disks or floppy diskettes. The thickness of the magnetic material may be chosen such that the magnetization direction is normal to the plane of the mesa 24. In one embodiment the magnetic layer 22 may be embedded in the stamp 20.

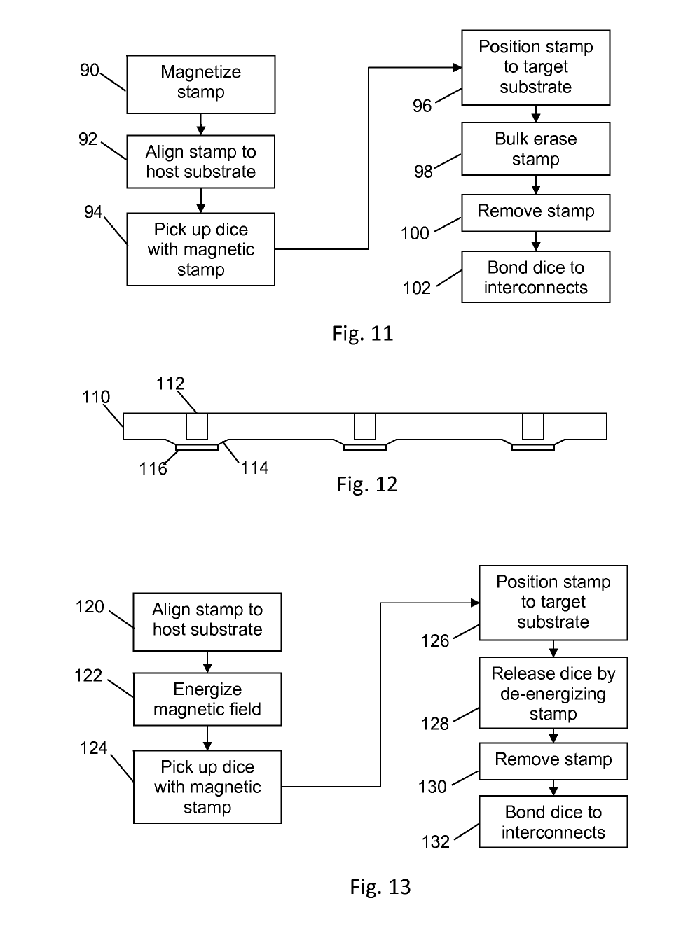

Referring to FIG. 11, there is shown a flow diagram of an alternative embodiment of the method relating to the sixth alternative embodiment with reference to FIG. 5. In step 90 of the flow diagram, the magnetic transfer stamp 20 is selectively magnetized using a write head, to form erasable permanent magnets 22 on the stamp 20. In step 92 of the flow diagram of FIG. 11, the stamp 20 is aligned to the host substrate 10A, such that the permanent magnets 22 on the stamp 20 approach or come into contact with the semiconductor dice 12 on the host substrate 10A. In step 94 of the flow diagram of FIG. 11, the semiconductor dice 12 that are aligned with the permanent magnets 22 on the stamp 20 are picked up by the magnetic stamp 20, as seen in FIG. 6. In step 96 of the flow diagram of FIG. 11, the magnetic stamp 20 is positioned in such a position as to transfer or attach the semiconductor dice 12 to the target substrate 30, as seen in FIG. 7. The magnetic stamp 20 is then, in step 98 of the flow diagram of FIG. 11, bulk erased with an external magnetic field, or otherwise. The stamp 20 is then removed in step 100 of the flow diagram of FIG. 11 and the semiconductor dice 12 are electrically bonded in step 102 of the flow diagram of FIG. 11 to the interconnects 32 on the target substrate 30, as seen in FIG. 8.

In a seventh alternative embodiment an electromagnetic transfer method is used. Referring to FIG. 12, an electromagnetic transfer stamp 110 is shown. An array of miniature solenoids 112 are located at mesas 114 in the stamp 110 that are coated with a ferromagnetic coating 116. The solenoids 112 selectively generate magnetic fields to magnetize or demagnetize selected ferromagnetic coatings 116. The array of electromagnet coils 112 may be individually addressable allowing for selective pick up of the semiconductor dice 12.

In step 120 of the flow diagram of FIG. 13, the electromagnetic stamp 110, in place of the magnetic stamp 20 with reference to FIG. 5, is brought into contact with the host substrate 10A and the selected solenoids 112 are energized in step 122 of the flow diagram of FIG. 13. Alternately, the selected solenoids 112 may be energized before the electromagnetic transfer stamp 110 is brought into contact with the semiconductor dice 12 on the host substrate 10A. In step 124 of the flow diagram of FIG. 13, the semiconductor dice 12 are picked up by the electromagnetic transfer stamp 110 as shown in FIG. 6, which may involve the breaking of tethers 14 or the degradation of adhesive layers using a laser lift-off technique. The stamp 110 is then positioned as shown in FIG. 7 so as to transfer in step 126 of the flow diagram of FIG. 13 the selected semiconductor dice 12A to the target substrate 30 as shown in FIG. 8. The transferred semiconductor dice 12A are then released in step 128 of the flow diagram of FIG. 13 by de-energizing the electromagnetic field in the ferromagnetic coatings 116. This may be achieved by de-energizing the solenoids 112 or by the use of transient ac and/or dc currents or current pulses in the solenoids. In an alternate embodiment, the ferromagnetic layers 116 may be omitted and the semiconductor dice may be picked up by the electromagnetic force of the solenoids. The solenoids may or may not have a magnetic core, depending on the embodiment selected. After the electromagnetic stamp has been removed in step 130 of the flow diagram of FIG. 13, the semiconductor dice 12A may be electrically bonded in 132 of the flow diagram of FIG. 13 to the interconnects 32 on the target substrate 30, as seen in FIG. 9.

In an eighth alternative embodiment, semiconductor dice 12A are transferred to the target substrate 30 without an adhesive coating on the target substrate, wherein the dice 12A are electrically bonded to the interconnects 32 before the magnetic or electromagnetic transfer stamp 110 is removed.

In a ninth embodiment, the electrical contacts of the semiconductor dice 12A are comprised of a ferromagnetic alloy.

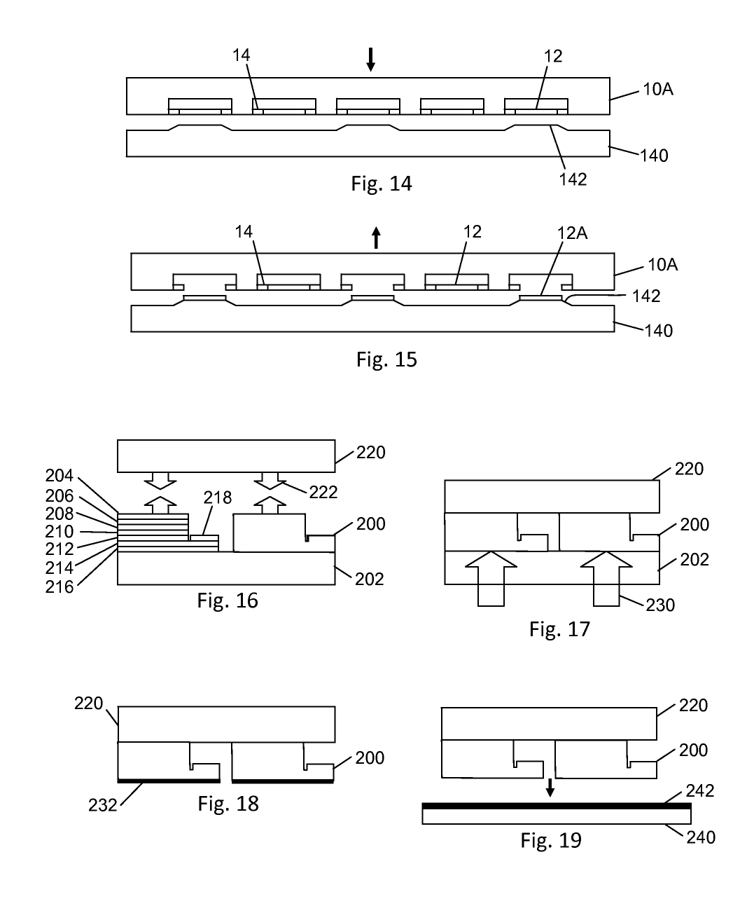

In a tenth alternative embodiment, the semiconductor dice 12A are directly transferred from the source substrate 10A to the target substrate 140 as indicated in FIGS. 14 and 15. Semiconductor dice 12A are attached to source substrate 10A by tethers 14. The target substrate 140 with magnetized mesas 142 is brought into conformal contact with the host substrate 140 whereupon selected semiconductor dice 12A are detached from tethers 14 and transferred to mesas 142 when the host substrate 10A and target substrate 140 are separated. The mesas 142 may then be demagnetized, or if they contain solenoids, de-energized.

In an eleventh alternative embodiment the magnetic field that is generated is designed such that both location and orientation of the semiconductor dice will hold during the transfer process from source substrate through target substrate. In one embodiment the orientation of the semiconductor dice may be guaranteed by breaking the rotational symmetry in the magnetic field of the mesa allowing a semiconductor dice to index.

In a twelfth embodiment, the semiconductor dice 12 may be partially or fully coated with one or more layers comprising ferromagnetic or ferrimagnetic materials, including cobalt, iron, nickel, and various metallic and rare-earth alloys as will be known to those skilled in the art of magnetic recording technologies, that can be selectively magnetized and demagnetized by application of an external magnetic field or localized heating by a laser.

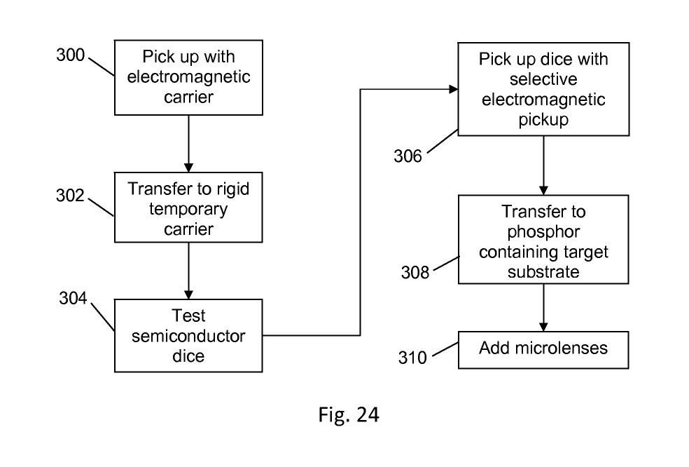

A thirteenth embodiment is shown in relation to FIGS. 16-23, in which another alternative method, as shown in the flow diagram of FIG. 24, is presented for using a magnetic layer on top of p-contact metal to improve manufacturing flow and overall design of micro-LED arrays.

In a fourteenth alternate embodiment the ferromagnetic photoresist may be applied to the LED dice after they had been transferred from the host substrate to a temporary adhesive transfer tape. This ferromagnetic material can be applied to the LED dice on the temporary substrate, preferably by a stamping process in which the material is applied to a smooth rigid substrate and the target substrate is pressed against the “inked” substrate in order to coat the LED dice only. The transferred ferromagnetic “ink” is then dried or otherwise hardened.

Referring to FIG. 16, micro-LEDs 200 are shown as formed on a host substrate 202, which may be a patterned sapphire wafer, for example. From top to bottom, the LEDs 200 each has a strata of multiple layers, including a cobalt layer 204, a reflector layer 206, a metal p-contact layer 208, a p-GsN:Mg layer 210, a light-emitting InGaN multi-quantum well layer 212, an n-GaN:Si layer 214 and a low melting point GaN layer 216. A metal n-contact layer 218 is also included. The cobalt (Co) containing layer 204 is used in order to create a magnetic force 222 between individual LEDs 200 and an electromagnetic carrier 220.

In step 300 of the flow diagram of FIG. 24, the LEDs 200, or semiconductor die, are picked up en masse by the electromagnetic carrier 220. FIG. 17 shows that pick-up of the LEDs 200 is enabled by laser-lifting the LEDs 200 from the host substrate 202 while contacted to the electromagnetic carrier 220. In the laser-lifting process, the low temperature melting point layer 216 on the bottom of the LEDs 200 is irradiated with ultraviolet laser radiation 230 at the interface with the sapphire substrate 202. The GaN layer 216 decomposes, at least in part, to gallium and nitrogen, reducing the bond strength of the LEDs 200 to the host substrate 202. FIG. 18 shows the picked-up LEDs 200 after irradiation with the laser. The LEDs 200 have been separated from the host substrate 202 by the electromagnetic carrier 220 and have on their underside a residual decomposition layer 232. This thin residual layer is cleaned away using HCl, KOH or other wet process.

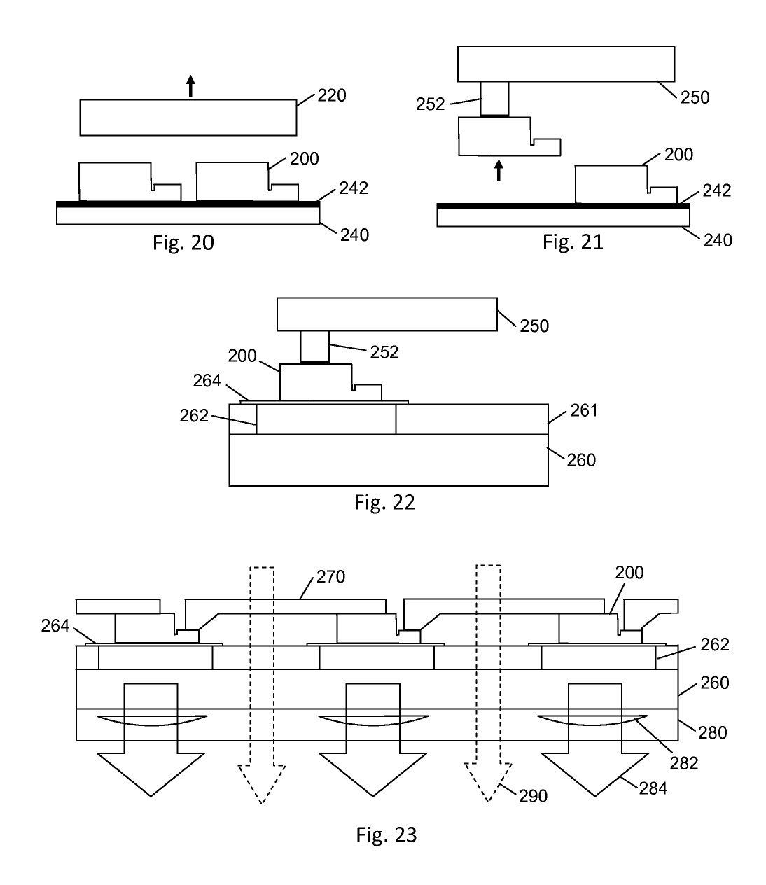

In step 302 of the flow diagram of FIG. 24, the LEDs 200 are then transferred to a temporary, rigid carrier 240. As shown in FIG. 19, in the transfer process the LEDs 200 are first brought by the electromagnet carrier 220 to the rigid temporary carrier 240, on top of which is an adhesive layer 242. Then, as shown in FIG. 20, the LEDs 200 are released by the electromagnetic carrier 220 onto the rigid temporary carrier 240.

In step 304 of the flow diagram of FIG. 14, the LEDs 200, while on the temporary carrier 240, may be tested for intensity and wavelength of light emission by passing current through them. Electrical contact from above may be made to the p-contact 208 layer, via the electrically conductive cobalt layer 204 and electrically conductive reflector layer 206, and the n-contact layer 218. LEDs 200 may be tested individually or in groups.

In step 306 of the flow diagram of FIG. 24, a selected LED 200 is picked up with a selective electromagnetic transfer device 250 and transferred to a light transmitting target substrate 260 with phosphor areas 262. FIG. 21 shows the selective electromagnetic pickup device 250, with one or more individually addressable pickup heads 252, that has been moved towards the LEDs 200 on the rigid temporary carrier 240, picked up an LED 200 from the rigid temporary carrier 240, and moved away.

In step 308 of the flow diagram of FIG. 24, the selected LED 200 picked up by the selective electromagnetic transfer device 250 is transferred to a light transmitting target substrate 260. FIG. 22 shows the LED 200, which was picked up by the selective electromagnetic pickup device 250, now transferred to the target substrate 260. The target substrate 260 may be transparent or translucent and may have thereon one or more areas 262 of phosphor, for conversion of the light emitted by the LEDs 200 to white light, for example. The target substrate 260 also may have thereon a light-transmitting upper portion 261 that may be a contiguous portion or a separate piece attached thereto. Alternatively, such portion 261 may be absent. A layer of transparent adhesive 264 may be used to bond the LED 200 to the phosphor containing zone or area 262.

In step 310 of the flow diagram of FIG. 24, an array of microlenses 282 is then applied to the target substrate 260. FIG. 23 shows an array of LEDs 200 that have been electromagnetically transferred to the target substrate 260. Electrical connections 270 are shown, connecting the LEDs 200 in series, although parallel connections may also be used. A layer 280 containing the array of microlenses 282 may also be applied to the substrate 260 on the opposite side of it to the LEDs 200.

In operation, the LEDs 200 emit light 284 that passes through the phosphor 262 and the microlenses 284. As the target substrate 260 is light transmitting, as may layer 280 be, the LED array assembly is transparent or translucent as a whole, allowing light 290 to pass through. When there is no power to the LEDs 200, an observer may look through the array structure or see light that has passed through it. When there is power to the LEDs, the brightness of light emitted by them will tend to dominate over any ambient light that is transmitted through the structure, which will then appear to an observer as a pixilated light source.

This embodiment allows for several desirable features, including: use of a thin film chip with n-side extraction; greater p-contact area for greater luminous efficiency per square micron of epitaxial material; a non-PDMS (polydimethlysiloxane) route to efficient transfer using magnetism, which is a far more selective force; the elimination of tethering, which consumes epitaxial area, to enable greater efficiency in the use of epitaxial area; and it may be more effective than semi-permanent bonding for laser lift-off yield.

In the description herein, embodiments disclosing specific details have been set forth in order to provide a thorough understanding of the invention, and not to provide limitation. However, it will be clear to one having skill in the art that other embodiments according to the present teachings are possible that are within the scope of the invention disclosed, for example the features described above may be combined in various different ways to form multiple variations of the invention. Furthermore, steps in the processes may be performed in a different order, and one or more steps may be omitted.

### REFERENCES

Guan, S., and B. J. Nelson. 2005. “Fabrication of Hard Magnetic Microarrays by Electrodeless Codeposition for MEMs Actuators,” Sensors and Actuators A 118:307-312.
Kobayashi, K, and K. Ikuta. 2008. “Three-Dimensional Magnetic Microstructures Fabricated by Microstereolithography,” Applied Physics Letters 92, 262505.
Lee, C.-Y., Z.-H. Chen, H.-T. Chang, C.-H. Cheng, and C.-Y. Wen. 2008. “Design and Fabrication of a Novel Micro Electromagnetic Acutator,” Proc. DTIP of MEMs & MOEMs. EDA Publishing.
MicroChem. Undated. SU-8 2000 Permanent Epoxy Negative Photoresist. Newton, Mass.: MicroChem.
Suter, M., S. Graf, O. Ergeneman, S. Schmid, A. Camenzind, B. J. Nelson, and C. Hierold. 2009. “Superparamagnetic Photosensitive Polymer Nanocomposite for Microactuators,” Proc. 15th International Conference on Solid-State Sensors, Actuators and Microsystems, pp. 869-872.

What is claimed is:

1. A method for transferring semiconductor dice from a host substrate to a target substrate, comprising the steps of:
providing a host substrate with semiconductor dice having magnetic portions;
magnetizing regions of a selected one of a transfer stamp or a target substrate; and
transferring the semiconductor dice from the host substrate to the magnetized regions of the selected one of the transfer stamp or target substrate by a magnetic force between the magnetized regions and portions when the host substrate is positioned adjacent to the selected one of the transfer stamp or target substrate,
wherein said transferring, when the selected one is the transfer stamp, also includes releasing the semiconductor dice from the transfer stamp to the target substrate.

2. The method of claim 1 wherein one or both of said magnetic regions of the transfer stamp and the magnetic portions of the semiconductor dice on the host substrate are permanent magnets.

3. The method of claim 1 wherein the selected one of the transfer stamp or target substrate includes spaced mesas formed thereon having said magnetized regions.

4. The method of claim 3 wherein each of the magnetized regions of the mesas is defined by a ferromagnetic coating that can be selectively magnetized or demagnetized.

5. The method of claim 4 wherein said ferromagnetic coating is selectively magnetized or demagnetized using a mechanically positioned magnetic write head.

6. The method of claim 4 wherein each of the magnetized regions of the mesas includes a solenoid operable to selectively generate a magnetic field to energize or de-energize the ferromagnetic coating.

7. The method of claim 1 wherein said magnetized portions are formed by a photoresist film with magnetic particles.

8. The method of claim 7 wherein said transferring the semiconductor dice to the selected one of the transfer stamp or the target substrate is by laser lift-off or release etching of the photoresist film.

9. A method for transferring semiconductor dice from a host substrate to a target substrate, comprising the steps of:
providing a host substrate with semiconductor dice having magnetic portions;
magnetizing regions of a transfer stamp;
removing semiconductor dice from a host substrate using the magnetized regions of the transfer stamp; and
releasing the semiconductor dice from the transfer stamp onto a target substrate by at least removing the transfer stamp or providing an adhesive force between the semiconductor dice and the target substrate that is greater than the magnetic force between the semiconductor dice and the transfer stamp.

10. The method of claim 9 wherein said magnetized regions of the transfer stamp are permanent magnets.

11. The method of claim 9 wherein the transfer stamp includes spaced mesas formed thereon having said magnetized regions.

12. The method of claim 11 wherein each of the magnetized regions of the mesas is defined by a ferromagnetic coating that can be selectively magnetized or demagnetized.

13. The method of claim 12 wherein the ferromagnetic coating is selectively magnetized or demagnetized using a mechanically positioned magnetic write head.

14. The method of claim 9 wherein said each of the magnetized regions of the mesas includes a solenoid operable to selectively generate a magnetic field to energize or de-energize the ferromagnetic coating.

15. The method of claim 9 wherein said magnetized portions are formed by a photoresist film with magnetic particles.

16. The method of claim 15 wherein said transferring the semiconductor dice to the transfer stamp is by laser lift-off or release etching of the photoresist film.

17. A transfer stamp for transferring semiconductor dice from a host substrate to a target substrate comprising:
a substrate; and
an array of magnetized regions thereon.

18. The stamp of claim 17 wherein said magnetized regions of the transfer stamp are permanent magnets on the transfer stamp.

19. The stamp of claim 17 wherein said substrate includes spaced mesas formed thereon having said magnetic regions.

20. The stamp of claim 19 wherein each of the magnetized regions of the mesas is defined by a ferromagnetic coating that can be selectively magnetized or demagnetized.

21. The stamp of claim 20 wherein said each of the magnetized regions of the mesas includes a solenoid operable to selectively generate a magnetic field to energize or de-energize the ferromagnetic coating.
